(19) United States
(12) Patent Application Publication
(10) Pub. No.: US 2026/0357412 A1
(43) Pub. Date: Nov. 12, 2026

(54) SOURCE AND DEPOSITION SYSTEM

(71) Applicant: Max-Planck-Gesellschaft zur Förderung der Wissenschaften e.V., München (DE)

(72) Inventors: Johannes Arnoldus BOSCHKER, Stuttgart (DE); Wolfgang BRAUN, Bietigheim-Bissingen (DE)

(21) Appl. No.: 19/488,322

(22) PCT Filed: Jun. 6, 2023
(86) PCT No.: PCT/EP2023/065134

§ 371 Date: Nov. 26, 2025

(51) Int. Cl. C23C 14/28; C23C 14/24; C23C 14/56

(52) U.S. Cl. CPC C23C 14/28; C23C 14/243; C23C 14/564

(57) ABSTRACT

The present invention relates to a source (100) for providing a directed flow of source material (80) thermally evaporated and/or sublimated by a laser beam (68) and emerging in a flow direction (84) from the source (100) at a flow opening (90) of a source chamber (10) of the source (100). Further, the present invention relates to a deposition system (200) for coating of a substrate (222), comprising a reaction chamber (210) enclosing a reaction volume (212), a substrate arrangement means (220) for arranging the substrate (222) to be coated within the reaction volume (212), and said source (100) for providing a directed flow (82) of evaporated and/or sublimated source material (80), wherein the reaction chamber (210) comprises a source opening (230) in a reaction chamber wall (216) of the reaction chamber (210) such that a line of sight (240) between the source opening (230) and the substrate (222) to be coated is free, and wherein the source (100) is sealingly arranged with its flow opening (90) at the source opening (230).

The invention relates to a source for providing a directed flow of source material thermally evaporated and/or sublimated by a laser beam and emerging in a flow direction from the source at a flow opening of a source chamber of the source. Further, the present invention relates to a deposition system for coating of a substrate, comprising a reaction chamber enclosing a reaction volume, a substrate arrangement means for arranging the substrate to be coated within the reaction volume, and said source for providing a directed flow of evaporated and/or sublimated source material, wherein the reaction chamber comprises a source opening in a reaction chamber wall of the reaction chamber such that a line of sight between the source opening and the substrate to be coated is free, and wherein the source is sealingly arranged with its flow opening at the source opening.

Thermal laser epitaxy (TLE) is a physical vapor deposition technique. It uses single element or compound sources that are heated by laser beams in order to thermally evaporate or sublimate the source material. Because the laser beams can be pre-pared with almost arbitrarily high power densities, extremely high temperatures are possible. This allows for the evaporation or sublimation of practically all elements of the periodic table with the same optical setup. Hence, thermal evaporation and/or sublimation of source material by an accordingly provided laser beam is a technique that provides multiple advantages over conventional techniques when evaporating materials.

Important design considerations when planning a TLE system are for instance the configuration of the ports for the laser entrance and the process monitoring, prevention of the coating of the laser entrance windows, and, last but not least, laser safety. These issues can be considered sufficiently and from scratch when a new deposition system based solely on TLE is designed.

Significant problems arise however, however, when the integration of a TLE setup into an existing deposition system is desired. First, it is not granted that the reaction chamber used in the deposition system comprises all necessary ports, and if present, whether these ports are suitable, for running the TLE setup, for instance for coupling in the laser beam. Further, also with respect to laser safety special precautions have to be made. Because the TLE process employs high power lasers, special care needs to be taken that the lasers can be operated safely, both to protect the users and the system itself. Many vacuum systems, in particular ultra-high vacuum systems, are made from thin wall pieces of stainless steel that are welded together. Stainless steel has a low thermal conductivity and therefore a hot spot emerges wherever a laser beam accidentally hits the walls or cryo-shroud of the chamber. This can result in leaks of the vacuum system. Also, a finite risk is present of parts inside the vacuum chamber other than the source material and the laser absorber being hit by a laser beam and thereby being damaged. Finally, most existing vacuum systems have viewports attached to them through which the laser beams can potentially escape. This would require additional measures in the laboratory in order to guarantee the safety of the people in the room.

In view of the above, it is an object of the present invention to provide an improved source for providing a directed flow of source material, and an improved deposition system which do not have the aforementioned drawbacks of the state of the art. In particular, it is an object of the present invention to provide an improved source for providing a directed flow of source material, and an improved deposition system which provide a safe, reliable and simple way of integrating a source based on TLE into an existing deposition system.

This object is satisfied by the respective independent patent claims. In particular, this object is satisfied by a source for providing a directed flow of source material according to independent claim 1, and by a deposition system according to claim 41. The dependent claims describe preferred embodiments of the invention. Details and advantages described with respect to the source according to the first aspect of the invention also refer to a deposition system according to the second aspect of the invention, and vice versa, if of technical sense.

According to a first aspect the invention, the object is satisfied by a source for providing a directed flow of source material thermally evaporated and/or sublimated by a laser beam and emerging in a flow direction from the source at a flow opening of a source chamber of the source, the source comprising
the source chamber comprising a source chamber wall enclosing a source volume, wherein the source volume is sealable with respect to the ambient environment,
the flow opening in the source chamber wall of the source chamber,
a source element providing the source material,
a source arrangement arrangeable within the source chamber for holding the source element within the source chamber, and
a laser means for providing the laser beam within the source volume,
   wherein
the laser means is constructed for directing the laser beam onto a surface of the source element formed by the source material for thermally evaporating and/or sublimating the source material below a plasma threshold of the source material and thereby producing the directed flow of evaporated and/or sublimated source material, and
the source arrangement is constructed for positioning and orienting the source element with respect to the flow opening such that the directed flow of evaporated and/or sublimated source material is directed towards and through the flow opening. The element defining the outer appearance of the source according to the present invention is the source chamber. A source chamber wall of the source chamber encloses a source volume, in which the evaporation and/or sublimation of the source material takes place. The source volume is sealable with respect to the ambient environment. Thereby the source volume is provided as confined space, whereby all environmental properties of said confined space, such as for instance pressure, temperature and/or atmosphere composition, can be controlled and/or adjusted. Further, the source chamber wall also comprises the flow opening from which the directed flow of evaporated and/or sublimated source material emerges.

Within the source chamber, the source according to the present invention comprises a source arrangement. Said source arrangement is constructed for holding a source element. The source element, in turn, provides the source material. In the sense of the present invention, the source element can for instance comprise a holding element, such as a crucible, in which the source material is confined. However, also self-supporting source elements completely consisting of the source material are possible. As source materials, all materials providable as solids or fluids can be used in a source according to the present invention. However, the source material preferably is an elemental material, in particular an elemental metal.

According to the present invention, the source material is thermally evaporated and/or sublimated by a laser beam. Preferably, a continuous or quasi continuous laser beam is used. The laser beam is provided within the source chamber and the source volume, respectively, by accordingly constructed laser means. Said laser means directs the laser beam onto a surface of the source material, the source material subsequently absorbs the energy of the laser beam at least partially, and thereby the source material is evaporated and/or sublimated.

In particular, the properties of the laser beam, for instance wavelength and/or power and/or intensity, are selected such that said evaporation and/or sublimation processes take place below a plasma threshold of the source material. Hence, pure thermal evaporation and/or sublimation are caused by the impinging laser beam. In other words, the source according to the present invention is a source based on thermal laser evaporation (TLE), comprising all advantages of the TLE process, such as for instance a high purity of source materials, high flux densities of the provided flows, and short response times when changes of the provided flow of source material are needed.

During the evaporation and/or sublimation process, the initial flow of the evaporated and/or sublimated source material comprises a distribution which peaks perpendicular to the surface of the source material. In other words, the initial directed flow of evaporated and/or sublimated source material peaks parallel to a surface normal of the source material.

According to the present invention, the source arrangement is constructed for positioning and orienting the source element with respect to the flow opening. Thereby, the source arrangement is enabled to position and orienting the surface of the source element, and hence the afore-mentioned initial flow of evaporated and/or sublimated source material. For this purpose, the source arrangement as a whole is preferably fixed at a position within the source volume, in particular by a connection and/or fixation to the source chamber wall. Further, the source arrangement comprises rigid and/or adjustable means for holding the source element in a position and orientation such that said initial flow direction of evaporated and/or sublimated source material points towards the flow opening. Preferably, said means are actively, in particular remotely, adjustable for providing a subsequent and/or continuous control of the position and of the orientation of the source element and hence of the initial flow direction. Providing the flow of evaporated and/or sublimated source material emerging from the flow opening of the source chamber can thereby be provided.

In summary, the source according to the present invention is constructed for providing a directed flow of evaporated and/or sublimated source material. A directed flow in the sense of the present invention is a flow of material, in which the evaporated and/or sublimated source material moves essentially in a common flow direction, and is simultaneously confined perpendicular to said flow direction. Directed flows with diameters ranging from several millimeters, for instance 10 to 40 mm, down to 10 μm or less, can be provided by the source according to the present invention.

Said directed flow of thermally evaporated and/or sublimated source material is provided at the flow opening of the source chamber, in particular emerging from the source chamber at the flow opening. In other words, the source according to the present invention is a closed system, which provides the directed flow of evaporated and/or sublimated source material for use at a different location, in particular and preferably in a deposition system. In other words, the source according to the present invention provides a safe, reliable and simple way of integrating a source based on TLE into an existing deposition system

Further, the source according to the present invention can be characterized in that the source chamber comprises coupling means for coupling the source to an external reaction chamber, wherein the coupling means is arranged at and/or around the flow opening. As mentioned above, the source according to the present invention is a closed source based on TLE processes. The directed flow of evaporated and/or sublimated source material provided at the flow opening of the source according to the present invention will in most of the applications of the inventive source be used in another vessel or chamber, in particular for a deposition on a substrate arranged in said vessel or chamber. By already providing suitable coupling means, a connection to said external vessel and/or chamber, for instance of an existing deposition system can be simplified. By providing said coupling means at and/or around the flow opening, a desired relative position and orientation of the source, and thereby a desired alignment of the directed flow of evaporated and/or sublimated source material, with respect to the external vessel or chamber can be adjusted and provided.

In addition, the source according to the present invention can comprise that the source chamber comprises aperture means with one or more aperture elements in and/or at the flow opening, wherein each of the one or more aperture elements comprises an aperture body with a continuous aperture opening for forming the directed flow of evaporated and/or sublimated source material, wherein the aperture body of each aperture element is arranged transversally to the flow direction of the directed flow of evaporated and/or sublimated source material. In other words, the respective aperture element blocks with its aperture body the directed flow of evaporated and/or sublimated source material, and only the part of the flow impinging on the aperture element at the aperture opening can pass the respective aperture element. Thereby the resulting flow of evaporated and/or sublimated source material after passing the respective aperture element is directly influenced by the size, shape, and position of the aperture opening of the respective aperture element. In addition to the possibility of cutting off unwanted edges of the flow distribution, a shape of the cross-section of the directed flow can be specifically influenced here by an appropriate choice of the shape of the aperture opening.

However, as the aforementioned adjustments of the flow of evaporated and/or sublimated source material are provided by blocking parts of the flow by the aperture body of the respective aperture element, a reduction of in the overall intensity of the resulting directed flow of evaporated and/or sublimated source material is caused. For this reason, the one or more aperture elements are preferably designed to be adapted to the respective application, on one hand to sufficiently adjust the properties of the flow, and on the other hand not to produce too great a loss of intensity.

The source according to the present invention can be improved by that the aperture means comprises an aperture actuator for actively adjusting a size and/or a shape and/or a position perpendicular to the flow direction, respectively, of the respective aperture opening of one or more of the one or more aperture elements. As mentioned above, the aperture opening of a respective aperture element defines with its size, shape, and position, respectively, the respective properties of the resulting flow of evaporated and/or sublimated source material after passing through the respective aperture element. Hence, by providing a suitably constructed aperture actuator for adjusting a size and/or a shape and/or a position, respectively, of one or more aperture openings, said properties of the resulting flow of evaporated and/or sublimated source material after passing the respective aperture element can be actively adjusted. Preferably, the aperture actuator can be remotely controlled for providing said adjustments of the resulting directed flow of evaporated and/or sublimated source material during operation of the source according to the present invention.

In addition, the source according to the present invention can also comprise that the aperture means comprises two or more, in particular 5 or more, preferably 10 or more, aperture elements, wherein the aperture openings of the respective aperture elements are arranged aligned and distanced to each other with respect to the flow direction of the directed flow of evaporated and/or sublimated source material. In most of the cases, the respective aperture element comprises a thickness along the flow direction which is small compared to its dimension perpendicular to the flow direction. Typical thicknesses of aperture elements are in the range of 0.1 mm to 5 mm. Thereby, after passing a respective aperture element, an angular dispersion of the flow of evaporated and/or sublimated source material is reduced by the blocking property of the aperture element, but nevertheless still present. However, by implementing two or more and/or said aperture elements aligned and distanced to each other with respect to the flow direction, each of the aperture elements further reduces the resulting angular dispersion. Thereby, the reduction of the angular dispersion results in that the flow of evaporated and/or sublimated source material present after the last one of the two or more aperture elements can be improved drastically.

The source according to the present invention can be improved further by that the aperture means comprises a distance actuator for actively adjusting a distance between two or more aperture elements selected from the two or more aperture elements. The distance between two apertures defines the spread of the flow of evaporated and/or sublimated source material present at the second of the two aperture elements caused by dispersion, the longer the distance, the wider the spread. Hence, by the possibility of actively adjusting said distance provided by the distance actuator, the ability of the selected aperture elements for reducing the dispersion can be adjusted. A shorter distance causes a smaller reduction of the dispersion accompanied by a likewise smaller reduction of the intensity of the resulting flow of evaporated and/or sublimated source material, and vice versa.

Further, the aforementioned aperture actuator and the aforementioned distance actuator can also be combined in a single actuator.

Further, the source according to the present invention can be characterized in that the source chamber comprises a sealing valve at and/or in the flow opening for sealing the flow opening with respect to the ambient environment. As mentioned above, the source chamber of the source is sealable with respect to the ambient environment. By providing a sealing valve at and/or in the flow opening, said sealing of the source chamber can be effected also at the flow opening without the need for external sealing devices. By that, for instance transporting the source from one location of operation to another can be provided without venting the source volume to the ambient atmosphere. Also, during operation, a sealing of the source chamber with respect to an attached deposition chamber can be provided, for instance if the deposition chamber has to be vented to exchange substrates to be coated. An increase in operational capability of the source according to the present invention, in particular with regards to a time required for starting an operation of the source, can be provided.

In addition, the source according to the present invention can comprise that the source chamber comprises a laser safety lock at and/or in the flow opening for preventing laser light from shining through the flow opening. For evaporation and/or sublimation of the source material, high intensity laser beams are used. However, said laser beams might cause harm if they impinge somewhere else than the source material, especially if not confined in the source chamber of the source. By providing a laser safety lock at and/or in the flow opening, the flow opening can be shut if necessary and no laser beam can escape from the source chamber through the flow opening. An overall safety when using the source according to the present invention can thereby be improved.

Additionally, or alternatively, the source according to the present invention can be characterized in that the source chamber comprises a laser sensor for detecting laser light shining through the flow opening. As mentioned above, laser beams used for evaporating and/or sublimating source material should not escape the source chamber as they might harm the environment due to their high intensity. By providing a laser sensor, the unfortunate case of such a failure can be detected. Measures for preventing harm to the environment, such as for instance switching off the laser beam and/or actively blocking the path of the laser beam, can be taken.

According to an improved embodiment of the source according to the present invention, the source chamber comprises an evaluation unit coupled to the laser sensor and further controlling a lock actuator of the source chamber for actuating the laser safety lock, wherein the evaluation unit is constructed for controlling the lock actuator for closing the laser safety lock when laser light shining through the flow opening is detected by the laser sensor. As described above, the laser sensor can detect a laser beam present and/or emerging at the flow opening. Further, the above-mentioned safety lock can be used for laser-proof closing of the flow opening. In this improved embodiment, said laser sensor and safety lock are supplemented by the evaluation unit and the lock actuator coupled to both, namely laser sensor and safety lock. An automated closing of the safety lock when a laser beam is detected by the laser sensor can thereby be provided. Hence, the overall safety when operating the source according to the present invention can be improved further.

Further, the source according to the present invention can comprise that the source chamber comprises one or more connectors at and/or in the flow opening for differential pumping. One of the major areas of application of the source according to the present invention is providing the directed flow of evaporated and/or sublimated source material for a deposition onto a substrate, wherein the substrate is arranged in a deposition chamber on which the source is attached. However, depending on the intended deposition process, a certain deposition atmosphere might be required in the deposition chamber. As said deposition atmosphere is not always the ideal atmosphere for the evaporation and/or sublimation process located in the source chamber, a different atmosphere has to be provided in the source chamber for enhancing the functioning of the source according to the present invention. By differential pumping, two different atmospheres in the deposition chamber and in the source chamber can be provided. Hence, by providing the connectors necessary for said differential pumping at and/or in the flow opening, the prerequisites for providing said different atmospheres can be provided.

Preferably, if the respective source according to the present invention comprises aperture means with two or more aperture elements, the connectors for the differential pumping can be arranged such that differential pumping of the volumes between the two or more aperture elements is possible. As the aperture elements with their respective aperture openings themselves restrict the exchange of gasses between the atmosphere in the source chamber and any other vessel arranged subsequently to the flow opening, the differential pumping can be supported by this arrangement of the connectors.

According to a first alternative embodiment of the source according to the present invention, the laser means comprises a laser source arranged within the source volume for providing the laser light. In other words, the source is fully self-sufficient with respect to the laser beam used for the evaporation and/or sublimation process. No external laser source has to be provided. Preferably, the source chamber provides the respective feed-throughs for the electrical connections of the laser source arranged within the source chamber.

According to a second alternative embodiment of the source according to the present invention, the laser means comprises guiding means arranged in the source chamber wall for guiding externally provided laser light into the source volume. In this embodiment, an external laser source provides laser light, and guiding means allow the provision of said laser light as laser beam used for the evaporation and/or sublimation process within the source chamber. In other words, the guiding means couple the laser light into the source chamber. As mentioned above, the used laser beams often comprise high power and/or intensity. Therefore, providing a suitable laser source in compliance with the size limitations caused by the limited space within the source chamber might be challenging at least. By providing suitable guiding means arranged in the source chamber wall of the source chamber, said size limitations can be avoided. The laser source of the laser light used as laser beam in the source according to the present invention is located externally with respect to the source chamber and can be of any size. Also, already existing laser sources can be (re-)used, if they are able to provide the necessary laser light, in particular with respect to wavelength and intensity. Thereby, also a cost reduction can be achieved.

The source according to the present invention can be improved further by that the guiding means comprises optical elements for adjusting a size and/or shape and/or focal length and/or direction of the externally provided laser light. The externally provided laser light might not comprise the ideal properties needed for the intended evaporation and/or sublimation processes of the source according to the present invention. By providing suitable optical elements, for instance lenses, apertures, mirrors, etc., the properties of the laser light can be adjusted for providing the ideal laser beam within the source chamber. Also altering the laser beam during operation, for instance after change of the source material to be evaporated and/or sublimated, can be provided. Preferably, the optical elements are actively adjustable, so that also a closed loop control of the properties of the laser beam during the operation of the source can be provided.

Further, the source according to the present invention can be characterized in that the source arrangement comprises a source actuator for actively positioning and orienting the source element and thereby the surface of the source material accessible to the laser beam. The source according to the present invention provides a directed flow of evaporated and/or sublimated source material emerging from the source chamber at the flow opening. As described above, the initial direction of the flow of evaporated and/or sublimated source material at the source element is aligned perpendicular to the surface of the source element, at which the evaporation and/or sublimation process takes place. By actively positioning and orienting the source element and hence said surface, two main advantages can be provided. On one hand, by accordingly aligning the surface with respect to the flow opening, for instance by directing a surface normal of the surface of the source element towards the flow opening, an initial direction of the flow of evaporated and/or sublimated source material towards and in particular through the flow opening, can be ensured. On the other hand, one may actively select the position of the surface of the source element at which the evaporation and/or sublimation process takes place. A spread of a material usage caused by the evaporation and/or sublimation process over a larger area on the surface of the source element can thereby be provided.

According to another embodiment, the source according to the present invention can comprise that the source arrangement is constructed for positioning and orienting two or more source elements providing base materials such that a selectable one of the two or more source elements is positioned and/or oriented with respect to the flow opening and with respect to the laser beam such that its base material is the source material. This embodiment allows switching between two or more source elements used in the evaporation and/or sublimation process. Each of the two or more source elements comprise a base material, which becomes the source material used for evaporation and/or sublimation, if the source arrangement positions and orients the respective source element into the laser beam. The respective base materials preferably can be different so that directed flows of different evaporated and/or sublimated source materials can be provided by the same source.

In yet another embodiment the source according to the present invention can be characterized in that the source arrangement is constructed for positioning and orienting two or more source elements providing base materials such that two or more of the two or more source elements are positioned and/or oriented with respect to the flow opening and with respect to the laser beam such that their base materials are the source material. In this embodiment, two or more flows of evaporated and/or sublimated source materials are simultaneously provided at the flow opening. The respective source materials, provided by different source elements, can be identical or, preferably, different. For the evaporation and/or sublimation of two or more source materials, the laser beam can for instance be split into several sub-beams, preferably one for each source material to be evaporated and/or sublimated. Additionally, or alternatively, also reusing the laser beam in the sense of directing the laser beam reflected at a first source element to another source element, is possible. As a third approach, also defocusing and expanding the laser beam for illuminating the two or more source elements can be implemented.

According to an improved embodiment, the source according to the present invention can comprise that the laser means provide a separate laser beam for each of the base materials which are the source material. Thereby each of the source elements can be provided with a laser beam comprising the specific properties suitably selected for the respective source material to be evaporated and/or sublimated. The separate laser beams can be provided by different laser sources. Also, different guiding means can be used for each of the different laser beams. However, if technically possible and suitable, the same devices can be used for the different laser beams, as long as the individual properties of the separate laser beams suitable for the evaporation and/or sublimation process for the selected source material can be provided.

In a further enhanced embodiment, the source according to the present invention can be characterized in that the one or more aperture elements comprise in their respective aperture bodies a separate aperture opening for each of the base materials which are the source material. By this, for each of the separate directed flows originating from the different source elements all advantages can be provided described above with respect to the aperture elements, in particular the possibility to actively select a size and/or shape and/or position of the respective directed flow, and the reduction in the dispersion of the respective flow.

Further, the source according to the present invention can comprise that the source chamber wall consists of aluminum. Aluminum is a lightweight but nevertheless strong solid material, which allows the construction of the source chamber with thin source chamber walls and low weight. In addition, a source chamber made of aluminum comprises a good thermal conductivity, in particular compared to chambers made from steel. This is of advantage if accidentally the laser beam hits the source chamber wall. The energy of the laser beam is absorbed by the material of the source chamber wall, and by the good thermal conductivity, it does not stay concentrated at the place of impact but is spread over a larger area, preferably over the whole source chamber. Damages to the source chamber up to holes melted in the source chamber wall by the laser beam can thereby be prohibited.

Additionally, the source according to the present invention can comprise that the source chamber comprises a cooling means for actively cooling the source chamber wall. Cooling the source chamber wall provides the advantage that the temperature of the source chamber, especially also the temperature present within the source volume, can be adjusted. Further, in the failure scenario described in the previous paragraph, the heat energy arising from absorbing a stray laser beam can also be transported away and balanced by such cooling means.

According to an improved embodiment of the source according to the present invention, the cooling means is at least partly integrated into the source chamber wall. By this measure, the thermal connection between the cooling means and the source chamber wall to be cooled can be improved. The overall cooling of the source chamber can thereby be enhanced.

In another enhanced embodiment of the source according to the present invention, the cooling means comprises cooling ducts for a flow of a coolant. A flow of a coolant in cooling ducts is a well-suited measure for transporting the thermal energy away from the source chamber. The thermal energy is absorbed by the coolant flowing through the cooling ducts thermally coupled to the source chamber wall, and subsequently the warmed coolant is transported away to an external heat sink. In particular, said cooling ducts can easily be integrated into the source chamber walls, for instance by providing respective bores in the source chamber wall, or by providing the source chamber wall as a multilayer shell with an interstitial used as cooling duct. An especially effective cooling of the source chamber can thereby be provided.

According to an improved embodiment of the source according to the present invention, for the coolant one or more members are selected from a group of members comprising air, water, liquid nitrogen, and/or liquid helium. This list is not closed, and also additionally liquids or fluids can be used as coolant. In particular, for the respective temperature range, a most suitable coolant can be selected.

In addition, the source according to the present invention can comprise that the source chamber comprises a beam dump arranged within the source volume for absorbing laser light reflected at the source arrangement and/or the source material. The laser beam used for evaporating and/or sublimating the source material is in most of the cases not completely absorbed by the source material, but reflected at least partially. By providing a dedicated beam dump, suitably arranged within the source volume along the expected path of the reflected laser beam, a direct hit of the reflected laser light onto the material of the source chamber wall can be prohibited. In particular, the beam dump can be explicitly constructed for absorbing the energy of the impinging laser light, for instance by providing an accordingly constructed geometry and/or by a connection to external cooling means.

In an enhanced embodiment, the source according to the present invention can be constructed such that the beam dump is arranged at the source chamber wall. Preferably, the position at the source chamber wall for arranging the beam dump is selected according to the expected path of the laser light reflected at and by the surface of the source material. As the beam dump can be directly arranged and fixed to the source chamber wall, additional fixation means can be avoided. An especially simple and simultaneously effective arrangement of the beam dump within the source volume can be provided.

According to an alternative embodiment of the source according to the present invention, the source chamber wall comprises a sealable dump opening for inserting the beam dump into the source volume. Likewise to the embodiment described in the previous paragraph, the position for arranging the beam dump is selected according to the expected path of the laser light reflected at the surface of the source material. However, according to this embodiment, the beam dump is provided in a sealable dump opening. This provides for instance the possibility to easily exchange the beam dump after use and/or for installing a beam dump suitably selected for the expected reflected laser light.

The source according to the present invention can be further improved by that the beam dump comprises an active dump cooling. As mentioned above, while absorbing of the reflected laser light the thermal energy stored in the beam dump is increased, in most of the cases drastically increased. By providing an active dump cooling, said stored thermal energy can be transported away from the beam dump, at least from the part of the beam dump absorbing the impinging laser light. Harm and/or damages caused by the impinging laser light to the beam dump can thereby be prohibited.

Further, the source according to the present invention can be enhanced by that the dump cooling is formed as part of the cooling means. In some of the embodiments of the source according to the present invention, cooling means are implemented for an overall cooling of the source chamber. In these embodiments, when also a beam dump with an active dump cooling is present, a connection of the dump cooling to the cooling means of the source chamber can be provided. In other words, the dump cooling is integrated into the cooling means, for instance by connecting cooling ducts present as part of the dump cooling to cooling ducts provided by the cooling means. An overall cooling of the source according to the present invention as a whole can thereby be provided and in particular be simplified.

According to another improved embodiment, the source according to the present invention can be characterized in that the beam dump comprises a dump sensor for monitoring the reflected laser light. The laser light reflected at the surface of the source element automatically carries information about said surface, for instance about a shape of the surface and/or about a roughness of the surface. Said information can be used to draw conclusions about the evaporation and/or sublimation processes caused by the impinging laser light. By providing a suitable dump sensor as part of the beam dump, monitoring the reflected laser light and hence measuring said information can be rendered possible.

In addition, the source according to the present invention can also comprise that the source chamber comprises a diagnostic means for monitoring the source arrangement and/or the source material. The position and orientation of the source element, especially of the surface of the evaporated and/or sublimated source material, is crucial for an effective operation of the source according to the present invention as a whole. Hence, by monitoring the source arrangement and/or the source material, an effective operation of the source according to the present invention can be monitored.

In an enhanced embodiment, the source according to the present invention can be constructed such that the diagnostic means is arranged within the reaction volume. In most of the applications, the overall positions of the source arrangement and/or the source element are stable not only during operation of the source according to the present invention, but also for several operations of the source, in particular with different source elements. Hence, arranging the diagnostic means for monitoring the source arrangement and/or the source material directly within the source volume, for instance directly at the source chamber wall, is an especially simple way of providing said diagnostic measurements. In particular, no external diagnostic means and accordingly provided openings in the source chamber wall are needed.

According to an alternative embodiment of the source according to the present invention, the source chamber wall comprises a sealable diagnostic opening, and the diagnostic means is arranged at and/or in and/or through the diagnostic opening. Likewise to the embodiment described in the previous paragraph, the diagnostic means is used for monitoring the source arrangement and/or the source material. However, according to this embodiment, the diagnostic means is provided at and/or in and/or through the diagnostic opening. This provides for instance the possibility to easily exchange the diagnostic means after use and/or for installing a diagnostic means suitably selected for implemented source arrangement and/or source material.

In addition, the source according to the present invention can be improved by that for the dump sensor and/or the diagnostic means one or more members are selected from a group of members comprising temperature probe, pyrometer, IR sensor, IR camera, and/or camera for visible light. This list is not closed, and also other suitable sensors can be used. In particular, by using a suitable sensor, a monitoring of a wide variety of properties of both the beam dump, and/or the source arrangement, and/or the source element, respectively, can be provided.

The source according to the present invention can further comprise that the source chamber comprises a sealable loading opening for exchanging the source material present in the source volume. The source according to the present invention can be used for providing directed flows of different evaporated and/or sublimated source materials. A sealable loading opening provides the possibility to exchange the source material used during the evaporation and/or sublimation, in particular for instance by exchanging the respective source element. A wide variety of different flows of evaporated and/or sublimated source materials can thereby be provided without the need of completely opening the source chamber.

According to a possible enhancement of the source according to the present invention, the loading opening comprises a load lock and/or a transfer manipulator. A load lock allows the insertion and/or exchange of source material, especially source elements, without venting the source volume. A transfer manipulator is a means which takes the source material from the loading opening, in particular from the load lock, and transports if to its place at and/or within the source arrangement, and vice versa. Reaching into the source volume with external tools, in particular with bare hands, can thereby be provided.

Preferably, the source according to the present invention comprises both, a load lock and a transfer manipulator, wherein the transfer manipulator is automatically and/or remotely actuated. Thereby, the source element to be exchanged can be put into the load lock, the load lock can be closed and sealed, and subsequently the exchange of source material takes place, without direct external interference.

Further, the source according to the present invention can be characterized in that the source chamber comprises a sealable atmosphere opening for providing a selectable source atmosphere present in the source volume. As mentioned above, the source chamber is sealable with respect to the environment. This provides the possibility to provide a source atmosphere within the source volume suitably selected for the intended evaporation and/or sublimation process. Providing sealable atmosphere openings in the source chamber wall in turn provides the possibility to exchange the atmosphere present within the source chamber. On one hand, an atmosphere present within the source chamber after sealing it, in most of the cases identical to the ambient atmosphere, can be removed from the source volume. On the other hand, the selected source atmosphere can be filled into the source chamber, filling the source volume. For both, removing and filling, respectively, a suitable gas system can be used.

Additionally, the source according to the present invention can be enhanced by that the source chamber comprises a gas system connected to the atmosphere opening, wherein the gas system is constructed for providing the selected source atmosphere present in the source volume. In this embodiment, the gas system mentioned in the previous paragraph is provided as part of the source according to the present invention. The source according to the present invention can thereby be provided without the need for an external gas system. A stand-alone ability of the source according to the present invention can thereby be enhanced.

According to a further improved embodiment of the source according to the present invention, for the source atmosphere one or more members are selected from a group of members comprising ambient air, molecular oxygen (O₂), ozone (O₃), plasma-activated oxygen (O₂*), ionized oxygen (O⁻), atomic oxygen (O), nitrogen (N), plasma-activated nitrogen (N), phosphorus (P), sulfur(S), selenium (Se), mercury (Hg), NH₃, N₂O, CH₄ and combinations of the foregoing. This list is not closed, and also other suitable gases and gaseous compositions can be used as source atmosphere.

In another embodiment, the source according to the present invention can be enhanced further by that the selected source atmosphere comprises a pressure selected in the range of 10⁻¹² hPa to 10⁴ hPa. A large range of pressures can be provided for different evaporation and/or sublimation processes. In particular, for each intended evaporation and/or sublimation process, the most suitable pressure can be selected.

According to a second aspect of the invention, the object is satisfied by a deposition system for coating of a substrate, comprising a reaction chamber enclosing a reaction volume, a substrate arrangement means for arranging the substrate to be coated within the reaction volume, and a source for providing a directed flow of evaporated and/or sublimated source material, wherein the reaction chamber comprises a source opening in a reaction chamber wall of the reaction chamber such that a line of sight between the source opening and the substrate to be coated is free, wherein the source is sealingly arranged with its flow opening at the source opening, and wherein the source is constructed according to the first aspect of the invention.

The deposition system according to the second aspect of the present invention comprises a source according to the first aspect of the present invention. Hence, the deposition system comprises and provides all features and advantages already described above in detail with respect to the source according to the present invention.

In the deposition system according to the present invention, the source provides the directed flow of source material, evaporated and/or sublimated by the laser beam. In other words, the source according to the present invention acts as an external TLE source within the deposition system according to the present invention. The directed flow enters the reaction chamber through the source opening, as the flow opening of the source is attached thereto. As the source opening is constructed such that between the source opening and the substrate to be coated, there is a free line of sight, the directed flow of evaporated and/or sublimated source material provided by the source flows through the reaction chamber and impinges onto the substrate held with the reaction volume by the substrate arrangement means. Thereby, a coating of the substrate by the evaporated and/or sublimated source material provided by the source according to the present invention can be ensured.

Further, the deposition system according to the present invention can comprise that the directed flow of evaporated and/or sublimated source material emerging from the source is aligned, preferably aligned in parallel, to the line of sight between the source opening and the substrate to be coated. As described above, the free line of sight between the source opening and the substrate to be coated ensures a deposition of the evaporated and/or sublimated source material provided by the source according to the present invention onto the substrate. By additionally aligning, preferably aligning in parallel orientation, the flow direction of the directed to said line of sight, it can be provided that the peak of the distribution of the directed flow of evaporated and/or sublimated source material impinges onto the substrate. The coating of the substrate can thereby be improved further.

In addition, the deposition system according to the present invention can be characterized in that the reaction chamber comprises connection means, and wherein the reaction chamber and the source chamber are coupled to each other by the connection means. During the deposition process, a fixed arrangement of the substrate to be coated and the directed flow of evaporated and/or sublimated source material relative to each other is of essential advantage. Said fixed arrangement can be provided for example by ensuring that the reaction chamber and the source chamber are fixed on each other. Connection means, for instance clamps, screws, accordingly constructed flanges, or similar devices, are suitable devices for providing said mutual fixation of the two chambers with respect to each other.

Preferably, the source chamber comprises coupling means and the reaction chamber comprises connection means. Especially, said coupling means and said connection means are constructed such that they can interact with each other. An especially good, tight, and firm connection between the source chamber and the reaction chamber can thereby be provided.

According to another embodiment of the deposition system according to the present invention, the reaction chamber comprises two or more source openings, wherein at each source opening a source according to the first aspect of the present invention is arranged. In other words, in this embodiment the deposition system according to the second aspect of the present invention comprises two or more external TLE sources according to the first aspect of the present invention. All features and advantages described above with respect to a single source according to the present invention, can be provided by each of the two or more sources present in this embodiment of the deposition system according to the present invention.

Additionally, or alternatively, the deposition system according to the present invention can also comprise that the reaction chamber comprises one or more additional source units for providing a flow of material to be deposited onto the substrate, wherein the one or more additional source units are arranged within the reaction chamber. In other words, in this embodiment, in addition to the source according to the present invention, the deposition system comprises one or more source units as additional sources for providing one or more flows of material to be deposited onto the substrate. Said source units can also be based on TLE for providing the respective flow of material, but also all other processes for providing flows of material are possible, for instance molecular beam epitaxy, sputtering, pulsed laser ablation, electron beam evaporation, electric heating of crucibles, etc. A wide variety of different compositions of material flows reaching the substrate to be deposited there can be provided.

The invention will be explained in detail in the following by means of embodiments and with reference to the drawings. In particular, in the figures are shown:

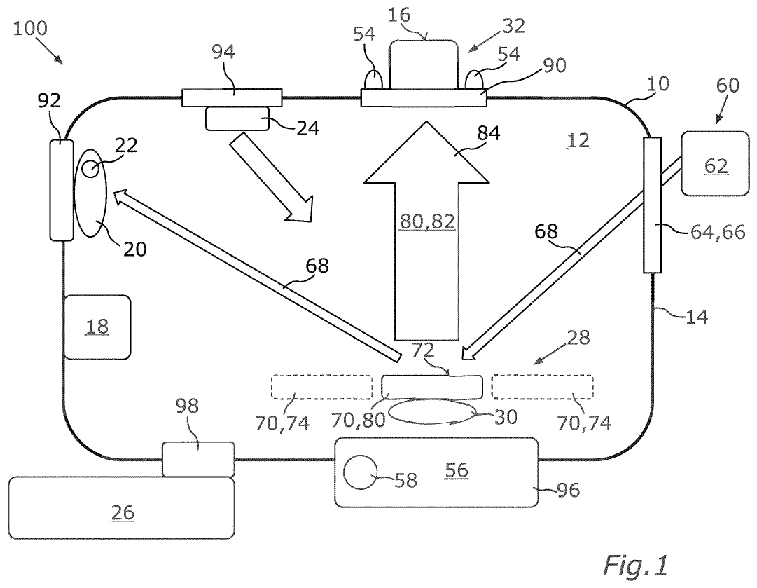

FIG. 1 A source according to the present invention,

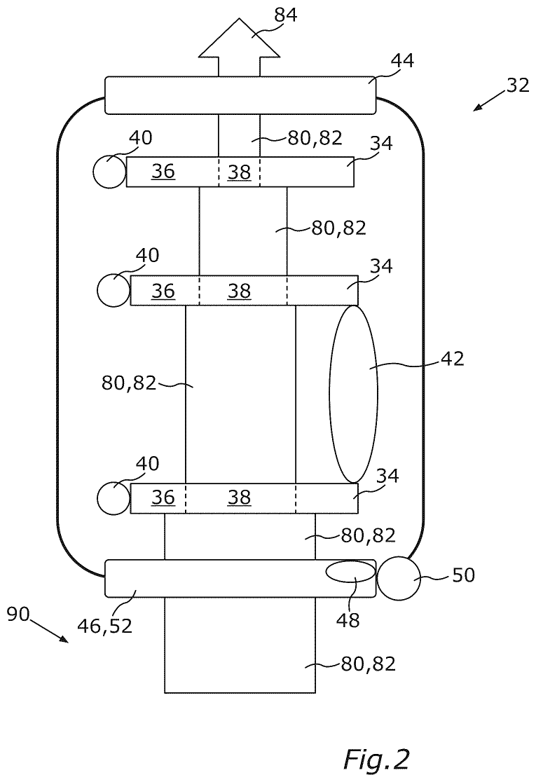

FIG. 2 Aperture means of a source according to the present invention, and

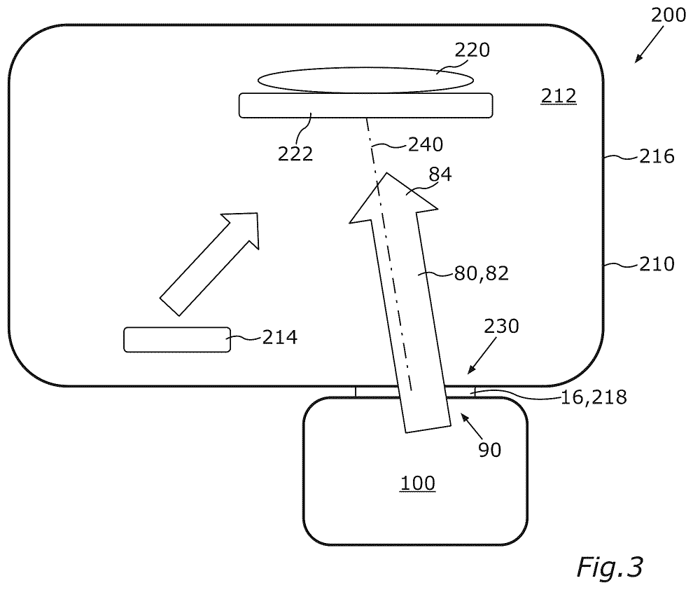

FIG. 3 A deposition system according to the present invention.

In FIG. 1 a schematic view of a source 100 according to the present invention is depicted. In particular, a view into a source chamber 10 of the source 100 is shown. A source chamber wall 14, preferably made of aluminum, encloses a source volume 12, which is sealable with respect to the ambient environment. Thereby, a gas system 26, which is connected to an atmosphere opening 98 provided in the source chamber wall 14, can comprise a selectable source atmosphere within the source volume 12. As source atmosphere a wide variety of gases or gas compositions including oxygen, nitrogen or ambient atmosphere can be used over a likewise wide pressure range selected in the range of 10⁻¹² hPa to 10⁴ hPa.

Laser means 60 provide a laser beam 68. In the depicted embodiment, an external laser source 62 is used and the provided laser beam 68 is guided into the source volume 12 by guiding means 64 arranged in and at the source chamber wall 14. The guiding means 64 also comprise optical elements 66 for adjusting the properties of the laser beam 68. In an alternative embodiment, which is not depicted, the laser source 62 can also be arranged within the source chamber 10.

The laser beam 68 is provided such that it impinges onto a surface 72 of a source material 80, provided as source element 70. The source element 70 is part of a source arrangement 28 and is positioned and oriented by a respective source actuator 30. As depicted in dashed lines, the source arrangement 28 can also provide more source elements 70, each with a base material 74. Said additional source elements 70 can be positioned and oriented by the source actuator 30 such that the respective base material 74 is illuminated by the laser beam 68 and hence be used as source material 80 in the sense of the present invention. Alternatively, but not depicted, also a simultaneous illumination of more than one source element 70 is possible, in particular also with a separate laser beam 68 for each of the used source elements 70.

The impinging laser beam 68 evaporates and/or sublimates the source material 80, which forms an initial directed flow 82 of evaporated and/or sublimated source material 80. The properties, in particular the wavelength and the intensity, of the laser beam 68 are selected such that the evaporation and/or sublimation process is provided below the plasma threshold of the respective source material 80. In other words, the source 100 according to the present invention is based on thermal laser evaporation (TLE). The source element 70 is positioned and oriented by the source actuator 30 such that the direction 84 of the directed flow 82 of source material 80 points towards a flow opening 90 in the source chamber wall 14.

At said flow opening 90, aperture means 32 can be arranged for forming the directed flow 82 of evaporated and/or sublimated source material 80. Possible embodiments of said aperture means 32 are described in detail below with respect to FIG. 2.

In particular, the directed flow 82 of evaporated and/or sublimated source material 80 is provided at the flow opening 90 and hence emerges from the source 100. In other words, the source 100 provides an external device for providing a directed flow 82 of source material 80 evaporated and/or sublimated by a laser beam 68. A possible usage of the source 100 according to the present invention is as an external TLE source 100 in a deposition system 200 (see FIG. 3). For that, the depicted embodiment of the source 100 already comprises coupling means 16 for a firm and fixed coupling to the respective part of the deposition system 200. Additionally, connectors 54 are arranged at the flow opening 90 for providing the possibility of differential pumping, if the atmosphere within the source volume 12 is different from an atmosphere within the deposition system.

As depicted, the laser beam 68 is in most of the cases not completely absorbed by the source element 70, but at least partly also reflected. For preventing harm and/or damages, a dedicated beam dump 20 is arranged at a selected position for absorbing the reflected laser beam 68. As depicted, a dump opening 92 can be present for an easy access to the beam dump 20. A dump sensor can be used for monitoring the absorbed laser beam 68, allowing an indirect investigation of the evaporation and/or sublimation process. In another and not depicted embodiment, the beam dump 20 can also comprise a dedicated dump cooling for cooling the beam dump 20.

Next to the beam dump 20, cooling means 18 are depicted. Said cooling means 18 are used for controlling the temperature of the source chamber 10. They can comprise for instance cooling ducts for a coolant integrated in the source chamber wall 14. Also, the dump cooling can be connected to the general cooling means 18 of the source 100.

Further, the source 100 according to the present invention can comprise diagnostic means 24 which directly monitor the evaporation and/or sublimation process. In FIG. 1, this monitoring is indicated by an arrow pointing from the diagnostic means 24 towards the surface 72 of the source material 80. The diagnostic means 24 can be arranged at a diagnostic opening 94 in the source chamber wall 14. The diagnostic means 24, and also the dump sensor 22 can be selected from a group of members comprising temperature probe, pyrometer, IR sensor, IR camera, and/or camera for visible light.

In addition, the depicted source chamber 10 also comprises a loading opening 96, through which the source element 70 providing the source material 80 can be brought into the source volume 12. As shown, a load lock 56 can be installed at the loading opening 96 for keeping the source volume 12 sealed during the installation process. A transfer manipulator 58 can be present for moving the respective source element 70 from the load lock 56 to the source arrangement 28.

FIG. 2 shows a schematic view of a possible embodiment of the aperture means 32 arranged at the flow opening 90. In the depicted embodiment, the aperture means 32 comprise three aperture elements 34, arranged along the flow direction 84 of the directed flow 82 of evaporated and/or sublimated source material 80. Each of the aperture elements 34 comprise an aperture body 36 and within the aperture body 36 an aperture opening 38. As is clearly visible, the respective aperture elements 34 form the flow 82 of source material 80 by partly blocking outer parts of the flow 82. Each of the aperture elements 34 is equipped with an aperture actuator 40, which are enabled for adjusting the size and/or shape and/or position of the aperture opening 38 of the respective aperture element 34. In addition, also a distance actuator 42 is depicted, which can adjust the relative position of two of the aperture elements 34 along the flow direction 84, and hence of the distance between said pair of aperture elements 34. In summary, an active adjustment of the form of the directed flow 82 of evaporated and/or sublimated source material 80 can be provided.

With respect to the flow direction 84 at the beginning of the aperture means 32, a safety lock 46 equipped with a respective lock actuator 52 are installed. Said safety lock 46 can be closed for preventing the laser beam 68 (see FIG. 1) from accidently shining through the flow opening 90. A laser sensor 48 is provided to monitor the flow opening 90 concerning a presence of the laser beam 68, and an evaluation unit 50 accordingly controls the lock actuator 52 for closing the safety lock 46, if the laser beam 68 should be detected. The depicted placement of the laser sensor 48 is only exemplary, the laser sensor 48 can also be placed such that the laser beam 68 can be detected somewhere outside of the source chamber 10, for instance also within the reaction chamber 210 (see FIG. 3), for a detection of the laser beam 68 at or near the substrate 222 to be coated.

On the respective upper end of the aperture means 32, a sealing valve 44 is provided. As already mentioned, the source 100 according to the present invention (see FIG. 1) is an external device, which can be used at different positions and/or locations. When moving from one location to another, the sealing valve 44 can be closed, and the source atmosphere present in the source 100 can be maintained. The depicted placement of the sealing valve 44 is only exemplary, the sealing valve 44 can also be arranged at the respective lower end of the aperture means 32, even an arrangement within the aperture means 32 between two aperture elements 34 is possible.

A deposition system 200 according to the present invention is depicted in FIG. 3. The deposition system 200 is equipped with a source 100 according to the present invention. The source 100 is arranged with its flow opening 90 at a source opening 230 in a reaction chamber wall 216 of a reaction chamber 210 of the deposition system 200. Connection means 218 of the reaction chamber 210 and coupling means 16 of the source 100 are used for providing a firm and secure connection of the source 100 at the reaction chamber 210.

Within a reaction volume 212 of the deposition system 200 a substrate 222 to be coated is provided, held in position by respective substrate arrangement means 220. The substrate 222 and the source opening 230 are provided such that a line of sight 240 between these to elements is kept free. The directed flow 82 of evaporated and/or sublimated source material 80 provided by the source 100 according to the present invention is provided such that its flow direction 84 is aligned in parallel to said line of sight 240. A deposition of the evaporated and/or sublimated source material 80 onto the substrate 222 can thereby be provided.

In the depicted embodiment, only one source 100 according to the present invention is shown as part of the deposition system 200 according to the present invention.

However, also two or more such sources 100 can be used with a single deposition system 200, alternatively and/or simultaneously. In addition, as depicted within the reaction volume 212 also additional source units 214 can be present for providing additional components for the intended coating of the substrate 222.

### LIST OF REFERENCES

10 Source chamber
12 Source volume
14 Source chamber wall
16 Coupling means
18 Cooling means
20 Beam dump
22 Dump sensor
24 Diagnostic means
26 Gas system
28 Source arrangement
30 Source actuator
32 Aperture means
34 Aperture element
36 Aperture body
38 Aperture opening
40 Aperture actuator
42 Distance actuator
44 Sealing valve
46 Safety lock
48 Laser sensor
50 Evaluation unit
52 Lock actuator
54 Connector
56 Load lock
58 Transfer manipulator
60 Laser means
62 Laser source
64 Guiding means
66 Optical element
68 Laser beam
70 Source element
72 Surface
74 base material
80 Source material
82 Directed flow
84 Flow direction
90 Flow opening
92 Dump opening
94 Diagnostic opening
96 Loading opening
98 Atmosphere opening
100 Source
200 Deposition system
210 Reaction chamber
212 Reaction volume
214 Source unit
216 Reaction chamber wall
218 Connection means
220 Substrate arrangement means
222 Substrate
230 Source opening
240 Line of sight

1-45. (canceled)

46. A source for providing a directed flow of source material as a closed system at a location different to the source, the flow of source material thermally evaporated and/or sublimated by a laser beam and emerging in a flow direction from the source at a flow opening of a source chamber of the source, the source comprising
the source chamber comprising a source chamber wall enclosing a source volume, wherein the source volume is constructed to be sealable with respect to the ambient environment,
the flow opening in the source chamber wall of the source chamber, source element providing the source material,
a source arrangement arrangeable within the source chamber for holding the source element within the source chamber, and
a laser means for providing the laser beam within the source volume,
wherein
the laser means is constructed for directing the laser beam onto a surface of the source element formed by the source material for thermally evaporating and/or sublimating the source material below a plasma threshold of the source material and thereby producing the directed flow of evaporated and/or sublimated source material, and
the source arrangement is constructed for positioning and orienting the source element with respect to the flow opening such that during operation of the source the directed flow of evaporated and/or sublimated source material is directed towards and through the flow opening,
characterized in that
the source chamber comprises coupling means for coupling the source to an external reaction chamber, wherein the coupling means is arranged at and/or around the flow opening.

47. The source according to claim 46,
wherein the source chamber comprises aperture means with one or more aperture elements in and/or at the flow opening, wherein each of the one or more aperture elements comprises an aperture body with a continuous aperture opening for forming the directed flow of evaporated and/or sublimated source material,
wherein the aperture body of each aperture element is arranged transversally to the flow direction of the directed flow of evaporated and/or sublimated source material.

48. The source according to claim 47,
wherein the aperture means comprises an aperture actuator for actively adjusting a size and/or a shape and/or a position perpendicular to the flow direction, respectively, of the respective aperture opening of one or more of the one or more aperture elements.

49. The source according to claim 47,
wherein the aperture means comprises two or more aperture elements, wherein the aperture openings of the respective aperture elements are arranged aligned and distanced to each other with respect to the flow direction of the directed flow of evaporated and/or sublimated source material.

50. The source according to claim 49,
wherein the aperture means comprises a distance actuator for actively adjusting a distance between two or more aperture elements selected from the two or more aperture elements.

51. The source according to claim 46,
wherein the source chamber comprises a sealing valve at and/or in the flow opening for sealing the flow opening with respect to the ambient environment.

52. The source according to claim 46,
wherein the source chamber comprises a laser safety lock at and/or in the flow opening for preventing laser light from shining through the flow opening.

53. The source according to claim 46,
wherein the source chamber comprises a laser sensor for detecting laser light shining through the flow opening.

54. The source according to claim 53,
wherein the source chamber comprises a laser safety lock at and/or in the flow opening for preventing laser light from shining through the flow opening,
and wherein the source chamber comprises an evaluation unit coupled to the laser sensor and further controlling a lock actuator of the source chamber for actuating the laser safety lock, wherein the evaluation unit is constructed for controlling the lock actuator for closing the laser safety lock when laser light shining through the flow opening is detected by the laser sensor.

55. The source according to claim 46,
wherein the source chamber comprises one or more connectors at and/or in the flow opening for differential pumping.

56. The source according to claim 46,
wherein the laser means comprises a laser source arranged within the source volume for providing the laser light.

57. The source according to claim 46,
wherein the laser means comprises guiding means arranged in the source chamber wall for guiding externally provided laser light into the source volume.

58. The source according to claim 57,
wherein the guiding means comprises optical elements for adjusting a size and/or shape and/or focal length and/or direction of the externally provided laser light.

59. The source according to claim 46,
wherein the source arrangement comprises a source actuator for actively positioning and orienting the source element and thereby the surface of the source material accessible to the laser beam.

60. The source according to claim 46,
wherein the source arrangement is constructed for positioning and orienting two or more source elements providing base materials such that a selectable one of the two or more source elements is positioned and/or oriented with respect to the flow opening and with respect to the laser beam such that its base material is the source material.

61. The source according to claim 46,
wherein the source arrangement is constructed for positioning and orienting two or more source elements providing base materials such that two or more of the two or more source elements are positioned and/or oriented with respect to the flow opening and with respect to the laser beam such that their base materials are the source material.

62. The source according to claim 61,
wherein the laser means provide a separate laser beam for each of the base materials which are the source material.

63. The source according to claim 61,
wherein the source chamber comprises aperture means with one or more aperture elements in and/or at the flow opening, wherein each of the one or more aperture elements comprises an aperture body with a continuous aperture opening for forming the directed flow of evaporated and/or sublimated source material,
wherein the aperture body of each aperture element is arranged transversally to the flow direction of the directed flow of evaporated and/or sublimated source material,
and wherein the one or more aperture elements comprise in their respective aperture bodies a separate aperture opening for each of the base materials which are the source material.

64. The source according to claim 46,
wherein the source chamber wall consists of aluminum.

65. The source according to claim 46,
wherein the source chamber comprises a cooling means for actively cooling the source chamber wall.

66. The source according to claim 65,
wherein the cooling means is at least partly integrated into the source chamber wall.

67. The source according to claim 65,
wherein the cooling means comprises cooling ducts for a flow of a coolant.

68. The source according to claim 67,
wherein for the coolant one or more members are selected from a group of members comprising air, water, liquid nitrogen, and/or liquid helium.

69. The source according to claim 46,
wherein the source chamber comprises a beam dump arranged within the source volume for absorbing laser light reflected at the source arrangement and/or the source material.

70. The source according to claim 69,
wherein the beam dump is arranged at the source chamber wall.

71. The source according to claim 69,
wherein the source chamber wall comprises a sealable dump opening for inserting the beam dump into the source volume.

72. The source according to claim 69,
wherein the beam dump comprises an active dump cooling.

73. The source according to claim 72,
wherein the source chamber comprises a cooling means for actively cooling the source chamber wall,
and wherein the dump cooling is formed as part of the cooling means.

74. The source according to claim 69,
wherein the beam dump comprises a dump sensor for monitoring the reflected laser light.

75. The source according to claim 46,
wherein the source chamber comprises a diagnostic means for monitoring the source arrangement and/or the source material.

76. The source according to claim 75,
wherein the diagnostic means is arranged within the reaction volume.

77. The source according to claim 75,
wherein the source chamber wall comprises a sealable diagnostic opening, and the diagnostic means is arranged at and/or in and/or through the diagnostic opening.

78. The source according to claim 74,
wherein for the dump sensor and/or the diagnostic means one or more members are selected from a group of members comprising temperature probe, pyrometer, IR sensor, IR camera, and/or camera for visible light.

79. The source according to claim 46,
wherein the source chamber comprises a sealable loading opening for exchanging the source material present in the source volume.

80. The source according to claim 79,
wherein the loading opening comprises a load lock and/or a transfer manipulator.

81. The source according to claim 46,
wherein the source chamber comprises a sealable atmosphere opening for providing a selectable source atmosphere present in the source volume.

82. The source according to claim 81,
wherein the source chamber comprises a gas system connected to the atmosphere opening, wherein the gas system is constructed for providing the selected source atmosphere present in the source volume.

83. The source according to claim 81,
wherein for the source atmosphere one or more members are selected from a group of members comprising ambient air, molecular oxygen (O₂), ozone (O₃), plasma-activated oxygen (O₂*), ionized oxygen (O−), atomic oxygen (O), nitrogen (N), plasma-activated nitrogen (N), phosphorus (P), sulfur(S), selenium (Se), mercury (Hg), NH₃, N₂O, CH₄ and combinations of the foregoing.

84. The source according to claim 81,
wherein the selected source atmosphere comprises a pressure selected in the range of 10⁻¹² hPa to 10⁴ hPa.

85. A deposition system for coating of a substrate, comprising a reaction chamber enclosing a reaction volume, a substrate arrangement means for arranging the substrate to be coated within the reaction volume, and a source for providing a directed flow of evaporated and/or sublimated source material,
wherein the reaction chamber comprises a source opening in a reaction chamber wall of the reaction chamber such that a line of sight between the source opening and the substrate to be coated is free,
wherein the source is sealingly arranged with its flow opening at the source opening, and
wherein the source is constructed according to claim 46.

86. The deposition system according to claim 85,
wherein the directed flow of evaporated and/or sublimated source material emerging from the source is aligned to the line of sight between the source opening and the substrate to be coated.

87. The deposition system according to claim 85,
wherein the reaction chamber comprises connection means, and wherein the reaction chamber and the source chamber are coupled to each other by the connection means.

88. The deposition system according to claim 85,
wherein the reaction chamber comprises two or more source openings, wherein at each source opening a source is arranged.

89. The deposition system according to claim 85,
wherein the reaction chamber comprises one or more additional source units for providing a flow of material to be deposited onto the substrate, wherein the one or more additional source units are arranged within the reaction chamber.
